(19) United States
(12) Patent Application Publication
(10) Pub. No.: US 2024/0290863 A1
(43) Pub. Date: Aug. 29, 2024

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Kuo-Cheng CHIANG, Zhubei City (TW); Guan-Lin CHEN, Baoshan Township (TW); Yu-Xuan HUANG, Hsinchu (TW); Jin CAI, Hsinchu City (TW); Chih-Hao WANG, Baoshan Township (TW)

(73) Assignee: Taiwan Semiconductor Manufacturing Company, Ltd., Hsinchu (TW)

(21) Appl. No.: 18/173,491

(22) Filed: Feb. 23, 2023

(51) Int. Cl. H01L 29/66; H01L 29/06; H01L 29/423; H01L 29/775; H01L 29/78; H01L 29/786

(52) U.S. Cl. CPC H01L 29/66545; H01L 29/0673; H01L 29/42392; H01L 29/66439; H01L 29/6656; H01L 29/775; H01L 29/7833; H01L 29/78696

(57) ABSTRACT

Semiconductor structures and methods for manufacturing the same are provided. The semiconductor structure includes a channel layer extending along a vertical direction, and a top S/D structure formed on the channel layer. The semiconductor structure also includes a bottom S/D structure formed below the channel layer, and a gate structure adjacent to the channel layer. The channel layer is surrounded by the gate structure. The semiconductor structure includes a top inner spacer layer formed on the gate structure, and a top surface of the channel layer is higher than a bottom surface of the top inner spacer layer.

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1C illustrate perspective views of intermediate stages of manufacturing a semiconductor structure in accordance with some embodiments.

FIGS. 2A to 2S illustrate cross-sectional representations of various stages of manufacturing the semiconductor structure shown along line A-A′ in FIG. 1C, in accordance with some embodiments.

FIG. 2S′ illustrate cross-sectional representations of a semiconductor structure, in accordance with some embodiments.

FIG. 2S″ illustrate cross-sectional representations of a semiconductor structure, in accordance with some embodiments.

FIGS. 3A to 3E illustrate cross-sectional representations of various stages of manufacturing a semiconductor structure, in accordance with some embodiments.

FIG. 4 is an enlarged cross-sectional representation of the semiconductor structure in the region A of FIG. 3D, in accordance with some embodiments.

FIG. 5 illustrates a cross-sectional representation of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a vertical channel layer which is surrounded by the gate structure. The top S/D structure is formed over the channel layer, and the bottom S/D structure is formed below the channel layer. The top S/D contact structure is formed over the top S/D structure, and the bottom S/D contact structure is formed below the bottom S/D structure. Since the distance between the gate structure and the top S/D contact structure is increased compared to the GAA device with horizontal channel layer, the capacitor between the gate structure and the top S/D contact structure is reduced. Therefore, the performance of the semiconductor structure is improved. The source/drain (S/D) structure or S/D region(s) may refer to a source or a drain, individually or collectively dependent upon the context.

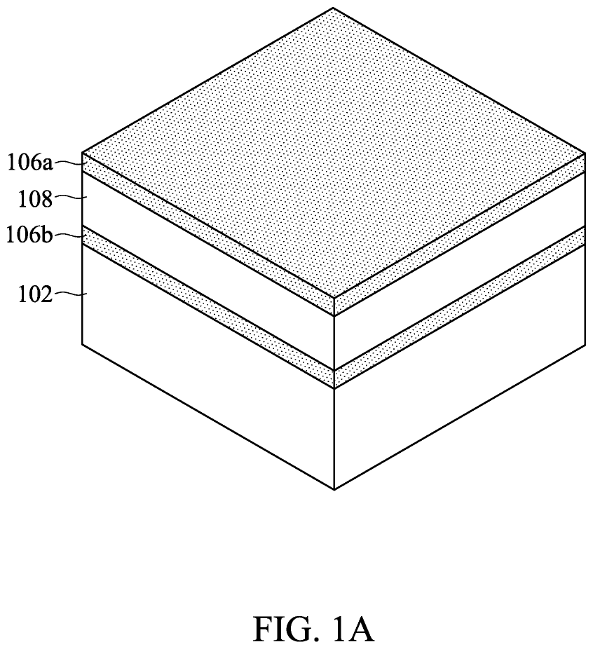

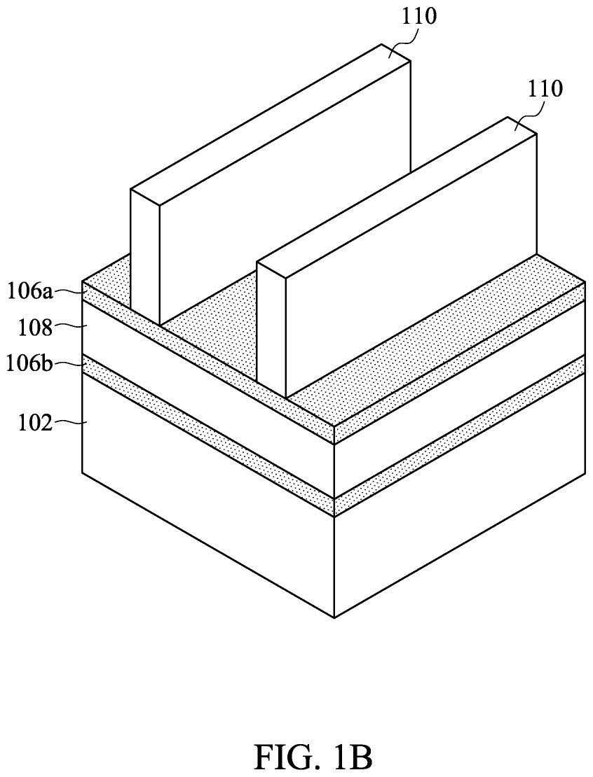

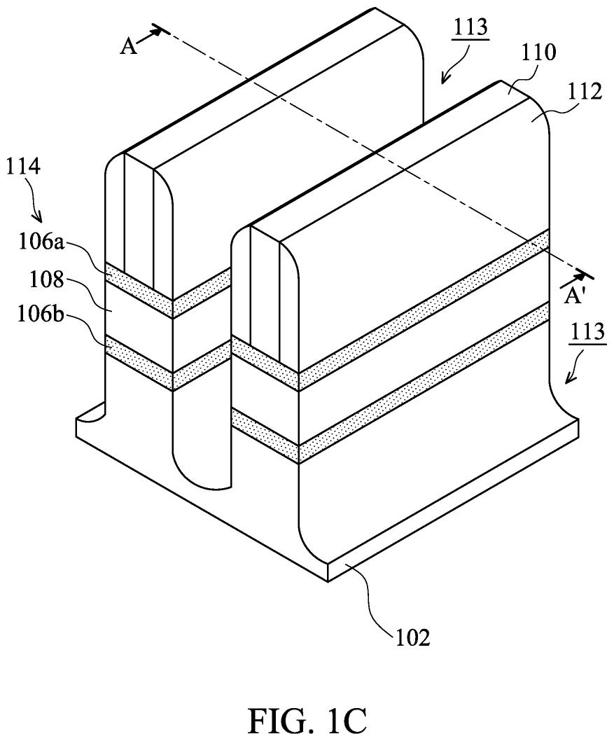

FIGS. 1A to 1C illustrate perspective views of intermediate stages of manufacturing a semiconductor structure 100a in accordance with some embodiments. As shown in FIG. 1A, a bottom first semiconductor material layer 10bb, a second semiconductor material layer 108 and a top first semiconductor material layer 106a are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the top first semiconductor material layer 106a, the bottom first semiconductor material layer 106b, the second semiconductor material layer 108 are alternately stacked over the substrate 102.

In some embodiment, the first semiconductor material layers 106a, 106b and the second semiconductor material layer 108 are made of different semiconductor materials.

In some embodiments, the first semiconductor material layers 106a, 106b are made of SiGe, and the second semiconductor material layer 108 is made of silicon (Si). It should be noted that the second semiconductor material layer 108 will become a vertical channel layer in the semiconductor structure 100a.

The first semiconductor material layers 106a, 106b and the second semiconductor material layer 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

As shown in FIG. 1B, after the first semiconductor material layers 106a, 106b and the second semiconductor material layer 108 are formed as a semiconductor material stack over the substrate 102, a mask layer 110 is formed over the semiconductor material stack, in accordance with some embodiments. Afterwards, the mask layer 110 is patterned.

The mask layer 110 may be a nitride layer, such as silicon nitride. In some embodiments, the mask layer 110 is formed by chemical vapor deposition (CVD), such as low-temperature chemical vapor deposition (LPCVD) or plasma-enhanced CVD (PECVD).

Next, as shown in FIG. 1C, spacer layers 112 are formed on opposite sidewall surfaces of the mask layer 110, in accordance with some embodiments. Next, portions of the first semiconductor material layers 106a, 106b and the second semiconductor material layer 108 are removed by using the mask layer 110 and the spacer layers 112 as a mask to form a recess 113. As a result, fin structures 114 are formed and recesses 113 are formed two adjacent fin structure 114.

The spacer layers 112 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the spacer layers 112 may include conformally depositing a dielectric material covering the mask layer 110 and the top first semiconductor material layers 106a over the substrate 102, and performing an anisotropic etching process, such as dry plasma etching, to remove a portion of the spacer layers 112.

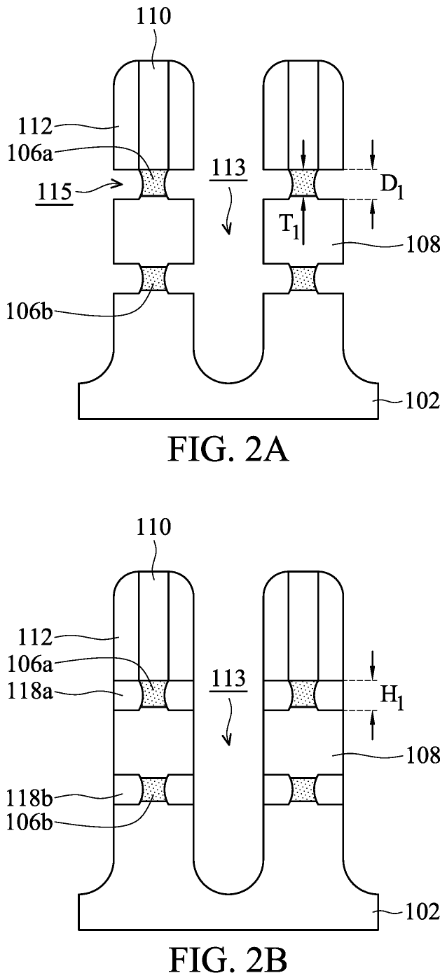

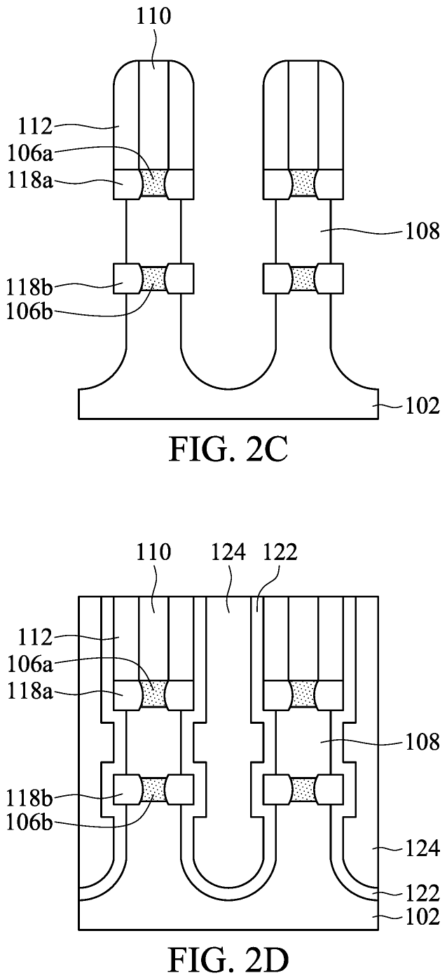

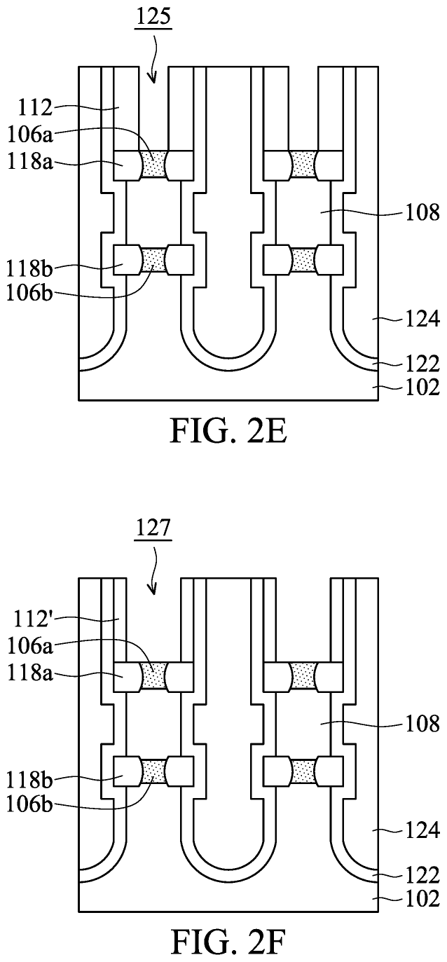

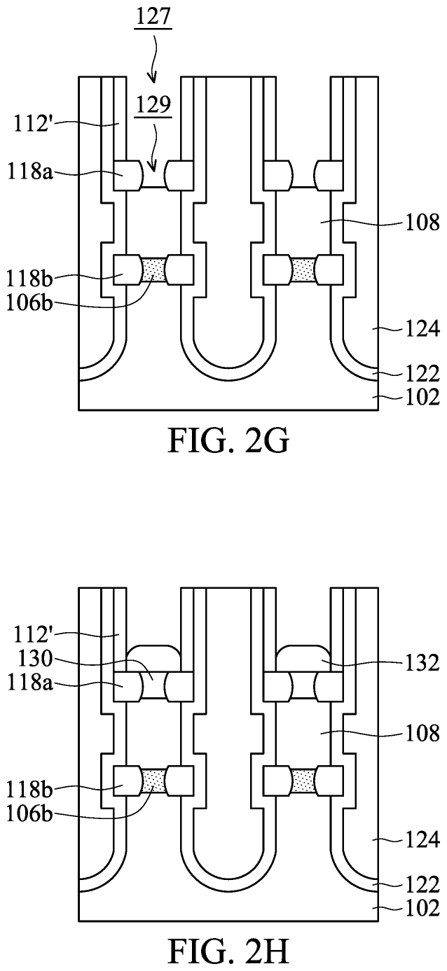

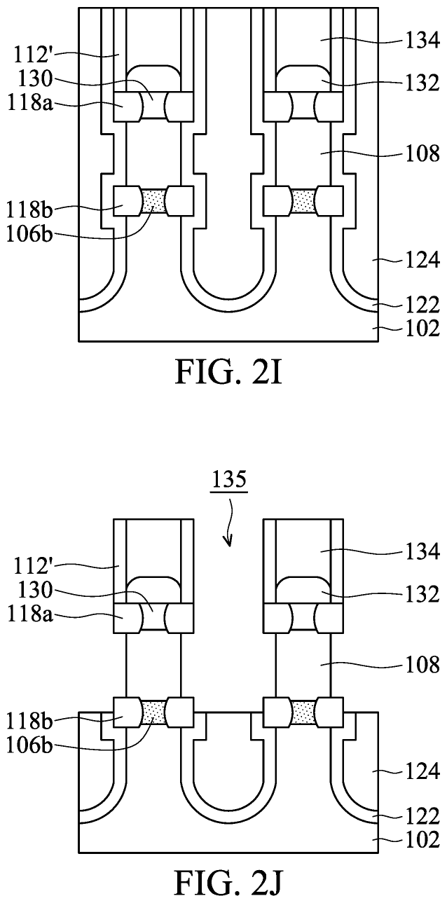

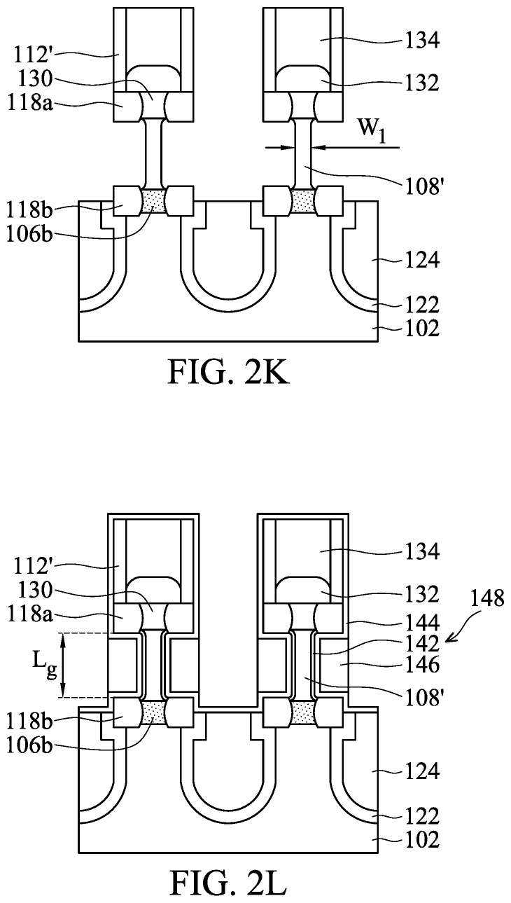

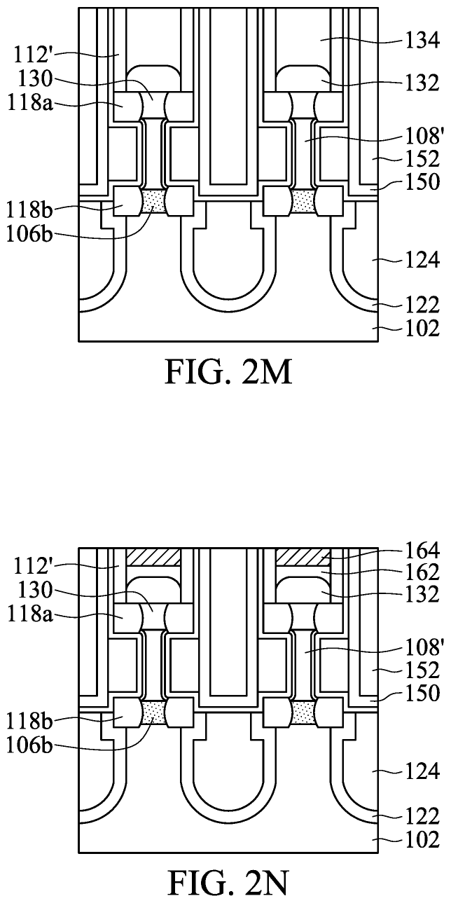

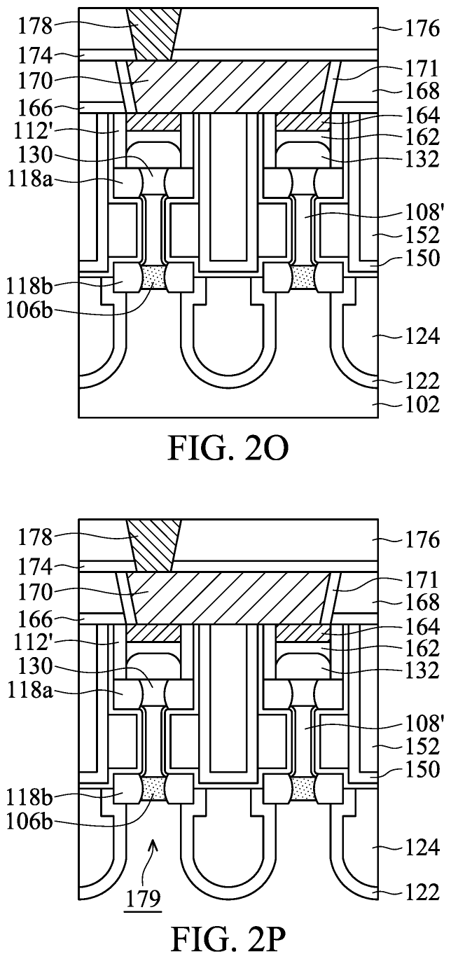

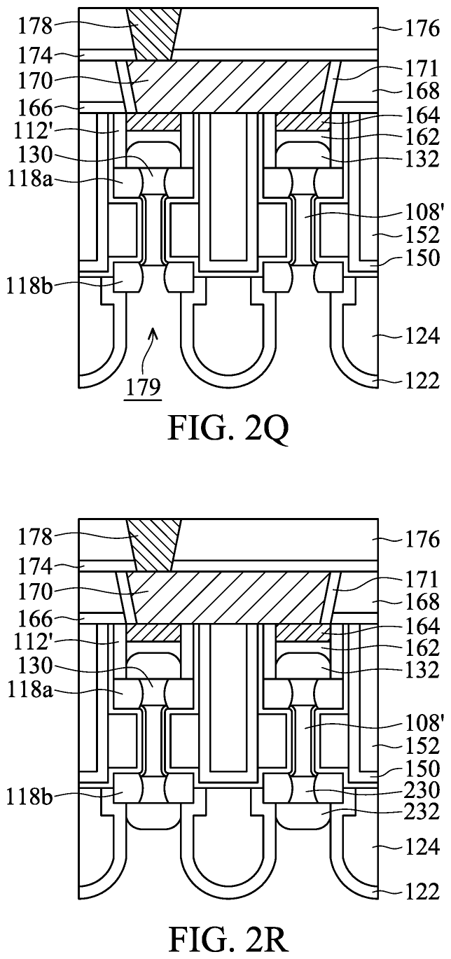

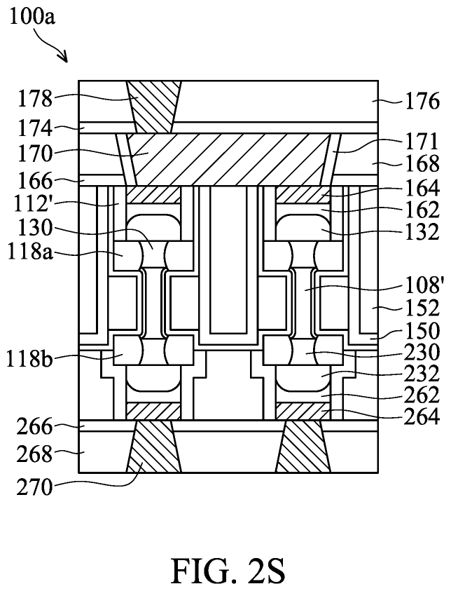

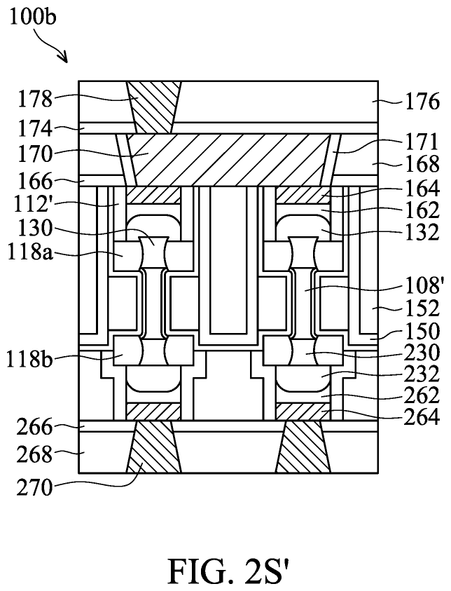

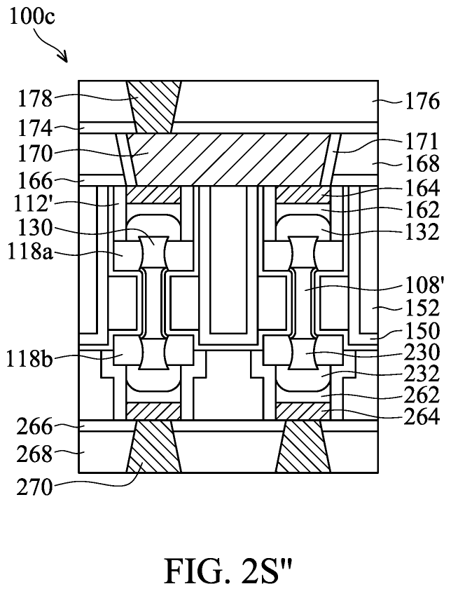

FIGS. 2A to 2S illustrate cross-sectional representations of various stages of manufacturing the semiconductor structure 100a shown along line A-A′ in FIG. 1C, in accordance with some embodiments. More specifically, FIG. 2A illustrates the cross-sectional representation shown along line A-A′ in FIG. 1C.

As shown in FIG. 2A, after the step of FIG. 1C, after the fin structures 114 are formed, portions of the top first semiconductor material layer 106a and portions of the bottom first semiconductor material layer 106b are removed to form notches 115, in accordance with some embodiments. The notches 115 are exposed by the recess 113. As a result, the etched first semiconductor material layers 106a, 106b have curved outer sidewall surfaces.

In some embodiments, an etching process is performed on the semiconductor structure 100a to laterally recess the top first semiconductor material layer 106a and the bottom first semiconductor material layer 106b. In some embodiments, during the etching process, the first semiconductor material layers 106a, 106b have a greater etching rate (or etching amount) than the second semiconductor material layer 108, thereby forming notches 115 between the second semiconductor material layer 108 and the substrate 102. In some embodiments, the etching process is an isotropic etching such as dry chemical etching, remote plasma etching, wet chemical etching, another suitable technique, and/or a combination thereof.

It should be noted that in addition to the top first semiconductor material layer 106a, the bottom first semiconductor material layer 106b, a portion of the second semiconductor material layer 108 is also removed. The notch 115 has a first depth D₁ along the vertical direction, and the top first semiconductor material layer 106a has a first thickness T₁along the vertical direction. Therefore, the first depth D₁ of the notch 115 is greater than the first thickness T₁ of the top first semiconductor material layer 106a. In some embodiments, the difference between the first depth D₁ of the notch 115 and the first thickness T₁ of the top first semiconductor material layer 106a is in a range from about 1 nm to about 2 nm.

Afterwards, as shown in FIG. 2B, a top inner spacer layer 118a and a bottom inner spacer layer 118b are formed in the notches 115, in accordance with some embodiments.

The top inner spacer layer 118a has a first height H₁ along the vertical direction. The first height H₁ of the top inner spacer layer 118a is greater than the first thickness T₁ of the top first semiconductor material layer 106a. In some embodiments, the inner sidewall surface of the top inner spacer layer 118a is curved, and the inner sidewall surface of the bottom inner spacer layer 118b is also curved. In some embodiments, the first height H₁ of the top inner spacer layer 118a is in a range from about 4 nm to about 15 nm. In some embodiments, the width of the top inner spacer layer 118a along the horizontal direction is in a range from about 4 nm to about 15 nm.

In some embodiments, the top inner spacer layer 118a and the bottom inner spacer layer 118b are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the top inner spacer layer 118a and bottom inner spacer layers 118b are formed by a deposition process, such as chemical vapor deposition (CVD) process, atomic layer deposition (ALD) process, another applicable process, or a combination thereof.

Next, as shown in FIG. 2C, after forming the top inner spacer layer 118a and bottom inner spacer layers 118b, the portions of the second semiconductor material layer 108 and the substrate 102 are removed, in accordance with some embodiments. As a result, the sidewall surface of the second semiconductor material layer 108 is not aligned with the sidewall surface of the top inner spacer layer 118a. The sidewall surface of the top inner spacer layer 118a extends beyond the sidewall surface of the second semiconductor material layer 108. The sidewall surface of the bottom inner spacer layer 118b extends beyond the sidewall surface of the second semiconductor material layer 108. The sidewall surface of the spacer layer 112 extends beyond the sidewall surface of the second semiconductor material layer 108.

In some embodiments, the portions of the second semiconductor material layer 108 and the substrate 102 are oxidized to form silicon oxide, and then the silicon oxide is removed by an etching process. The second semiconductor material layer 108 and the substrate 102 are gradually thinned by performing the cycles of the oxidation process and the etching process for several times.

The portions of the second semiconductor material layer 108 and the substrate 102 are removed by an etching process. In some embodiments, the etching process is an isotropic etching such as dry chemical etching, remote plasma etching, wet chemical etching, another suitable technique, and/or a combination thereof

Afterwards, as shown in FIG. 2D, the liner layer 122 is conformally formed on the mask layer 110, the spacer layer 112, the top inner spacer layer 118a and the bottom inner spacer layers 118b, the second semiconductor material layer 108 and the substrate 102, and then an isolation material is formed on the liner layer 122, in accordance with some embodiments. Next, a planarization process such as CMP process or an etch-back process may be performed until the mask layer 110 is exposed. As a result, an isolation structure 124 is formed.

The isolation structure 124 is configured to electrically isolate active regions (e.g. the fin structure 114) of the semiconductor structure 100a and is also referred to as shallow trench isolation (STI) feature in accordance with some embodiments.

In some embodiments, the liner layer 122 is made of silicon nitride. In some embodiments, the liner layer 122 is formed by chemical vapor deposition (CVD), physical vapor deposition, (PVD), atomic layer deposition (ALD), or other applicable processes. In some embodiments, the isolation structure 124 is made of silicon oxide, silicon nitride, silicon oxynitride (SiON), another suitable insulating material, or a combination thereof. In some embodiments, the isolation structure 124 is formed by chemical vapor deposition (CVD), physical vapor deposition, (PVD), atomic layer deposition (ALD), or other applicable processes.

Afterwards, as shown in FIG. 2E, the mask layer 110 is removed to form an opening 125, in accordance with some embodiments. The top surface of the top first semiconductor material layer 106a is exposed by the opening 125. The width of the opening 125 is substantially equal to the width of the top first semiconductor material layer 106a.

Since the spacer layer 112 has a greater etching selectivity with respect to the mask layer 110, the mask layer 110 is completely removed while the spacer layer 112 is not removed.

Next, as shown in FIG. 2F, a portion of the spacer layer 112 is further removed to form a thinned spacer layer 112′ in order to expose more area of the top first semiconductor material layer 106a, in accordance with some embodiments. In addition to the top first semiconductor material layer 106a, the top surface of the top inner spacer layer 118a is also exposed. In some embodiments, the width of the thinned spacer layer 112′ is smaller than the width of the top inner spacer layer 118a.

Afterwards, as shown in FIG. 2G, the top first semiconductor material layer 106a is removed to expose the top surface of the second semiconductor material layer 108, in accordance with some embodiments. As a result, a trench 129 is formed.

Since the top first semiconductor material layer 106a and the second semiconductor material layer 108 are made of different materials and have different etching rates, the second semiconductor material layer 108 is not removed while removing the top first semiconductor material layer 106a.

Afterwards, as shown in FIG. 2H, a top lightly doped drain (LDD) layer 130 is formed in trench 129, and a top source/drain (S/D) structure 132 is formed on the top LDD layer 130, in accordance with some embodiments. The top LDD layer 130 has curved sidewall surfaces in direct contact with the curved sidewall surface of the top inner spacer layer 118a.

The top S/D structure 132 is formed on and in direct contact with the top LDD layer 130 and the top inner spacer layer 118a. The top S/D structure 132 is in direct contact with the interface between the top LDD layer 130 and the top inner spacer layer 118a. The top S/D structure 132 is surrounded by the thinned spacer layer 112′.

The top surface of the top LDD layer 130 is substantially leveled with the top surface of the top inner spacer layer 118a. The bottom surface of the top LDD layer 130 is higher than the bottom surface of the top inner spacer layer 118a. The top S/D structure 132 extends above the top inner spacer layer 118a. The thinned spacer layer 112′ is formed on the top inner spacer layer 118a, and the thinned spacer layer 112′ is in direct contact with the top S/D structure 132.

In some embodiments, the top LDD layer 130 is made of any applicable material, such as Ge, Si, GaAs, AlGaAs, SiGe, GaAsP, SiP, SiC, SiCP, or a combination thereof. In some embodiments, the top LDD layer 130 is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the top S/D structures 132 are made of any applicable material, such as Ge, Si, GaAs, AlGaAs, SiGe, GaAsP, SiP, SiC, SiCP, or a combination thereof. In some embodiments, the top S/D structures 132 are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the top S/D structures 132 are in-situ doped during the epitaxial growth process. For example, the top S/D structures 132 may be the epitaxially grown SiGe doped with boron (B). For example, the S/D structures 132 may be the epitaxially grown Si doped with carbon to form silicon: carbon (Si:C) source/drain features, phosphorous to form silicon: phosphor (Si:P) source/drain features, or both carbon and phosphorous to form silicon carbon phosphor (SiCP) source/drain features. In some embodiments, the top S/D structures 132 are doped in one or more implantation processes after the epitaxial growth process.

Next, as shown in FIG. 2I, a mask layer 134 is formed over the top S/D structures 132, in accordance with some embodiments. The mask layer 134 covers the top S/D structures 132, and the mask layer 134 is in direct contact with the thinned spacer layer 112′. A mask material is formed on the isolation structure 124, the thinned spacer layer 112′ and the top S/D structures 132, and then a planarization process such as CMP or an etch-back process may be performed until the thinned spacer layer 112′ is exposed.

The mask layer 134 and the thinned spacer layer 112′ are made of different materials. The mask layer 134 may be a nitride layer, such as silicon nitride. In some embodiments, the mask layer 134 is formed by chemical vapor deposition (CVD), such as low-temperature chemical vapor deposition (LPCVD) or plasma-enhanced CVD (PECVD).

Afterwards, as shown in FIG. 2J, the top portion of the isolation structure 124 and the liner layer 122 are removed to form a trench 135, in accordance with some embodiments. The sidewall surface of the second semiconductor layer 108 is exposed by the trench 135. In addition, an entirety of the sidewall surface of the top inner spacer layer 118a is exposed. The thinned spacer layer 112′ is also exposed by the trench 135. However, a portion of the sidewall surface of the bottom inner spacer layer 118b is exposed. The bottom portion of the sidewall surface of the bottom inner spacer layer 118b is still covered by the liner layer 122 and the isolation structure 124.

In some embodiments, the top portion of the isolation structure 124 and the liner layer 122 are removed by the etching process. The etching process may be an isotropic etching such as dry chemical etching, remote plasma etching, wet chemical etching, another suitable technique, and/or a combination thereof.

Next, as shown in FIG. 2K, the exposed second semiconductor layer 108 is further removed to form a channel layer 108′, in accordance with some embodiments. Since the channel layer 108′ is vertical to the substrate 102, the semiconductor structure 100a with the vertical channel layer 108′ is a vertical GAA device.

The channel layer 108′ has a first width W₁ along the horizontal direction. In some embodiments, the first width W₁ of the channel layer 108′ is in a range from about 3 nm to about 15 nm. The first width W₁ of the channel layer 108′ along the horizontal direction is smaller than the width of the top LDD layer 130.

In some embodiments, the channel layer 108′ has an I-shaped structure. The channel layer 108′ has a top portion with a top width, a middle portion width a middle portion and a bottom portion with a bottom portion. The sidewall surface of the top portion of the channel layer 108′ is in direct contact with the sidewall surface of the top inner spacer layer 118a, and the sidewall surface of the bottom portion of the channel layer 108′ is in direct contact with the sidewall surface of the bottom inner spacer layer 118b.

The middle width of the middle portion along the horizontal direction is smaller than the top width of the top portion and the bottom width of the bottom portion. The topmost surface of the channel layer 108′ is higher than the bottom surface of the top inner spacer layer 118a. The bottommost surface of the channel layer 108′ is lower than the top surface of the bottom inner spacer layer 118b. In other words, the top surface of the bottom inner spacer layer 118b is higher than the bottommost surface of the channel layer 108′.

Afterwards, as shown in FIG. 2L, a gate structure 148 is formed to surround the channel layer 108′, in accordance with some embodiments. In some embodiments, the gate structure 148 includes an interfacial layer 142, a gate dielectric layer 144, and a gate electrode layer 146. The gate structure 148 is formed between the top inner spacer layer 118a and the bottom inner spacer layer 118b. The gate structure 148 is in direct contact with the top inner spacer layer 118a and the bottom inner spacer layer 118b. The gate dielectric layer 144 of the gate structure 148 is in direct contact with the thinned spacer layer 112′, the liner layer 122, the isolation structure 124, the top inner spacer layer 118a and the bottom inner spacer layer 118b.

The gate structure 148 includes a first portion and a second portion, and the channel layer 108′ is between the first portion and the second portion. The topmost surface of the channel layer 108′ is higher than the top surface of the gate electrode layer 146. The topmost surface of the interfacial layer 142 is higher than the top surface of the gate electrode layer 146.

In some embodiments, the interfacial layers 142 are oxide layers formed around the channel layer 108′. In some embodiments, the interfacial layers 142 are formed by performing a thermal process.

In some embodiments, the gate dielectric layers 144 are formed over the interfacial layers 144, so that the channel layer 108′ are surrounded (e.g. wrapped) by the gate dielectric layers 144. In some embodiments, the gate dielectric layers 144 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate dielectric layers 144 are formed using chemical vapor deposition (CVD), atomic layer deposition (ALD), another applicable method, or a combination thereof.

In some embodiments, the gate electrode layers 146 are formed on the gate dielectric layer 144. In some embodiments, the gate electrode layers 146 are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layers 146 are formed using chemical vapor deposition (CVD), atomic layer deposition (ALD), electroplating, another applicable method, or a combination thereof. Other conductive layers, such as work function metal layers, may also be formed in the gate structures 148, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layers 142, the gate dielectric layers 144, and the gate electrode layers 146 are formed, an etch-back process may be performed until the sidewall surface of the gate electrode layer 146 is aligned with the outer sidewall surface of the gate dielectric layer 144.

The gate structure 148 has a gate length Lg along the vertical direction. In some embodiments, the gate length Lg of the gate structure 148 is in a range from about 8 nm to about 25 nm.

Next, as shown in FIG. 2M, after the gate structure 148 is formed, a contact etch stop layer (CESL) 150 is conformally formed to cover gate structure 148 and an interlayer dielectric (ILD) layer 152 is formed over the CESL 150, in accordance with some embodiments. The CESL 150 is in direct contact with the gate dielectric layer 144 and the gate electrode layer 146 of the gate structure 148. The bottom surface of the CESL 150 is lower than the top surface of the top inner spacer layer 118a and the bottom surface of the channel layer 108′.

In some embodiments, the contact etch stop layer 150 is made of a dielectric materials, such as silicon nitride, silicon oxide, silicon oxynitride, another suitable dielectric material, or a combination thereof. The dielectric material for the contact etch stop layers 150 may be conformally deposited over the semiconductor structure by performing chemical vapor deposition (CVD), ALD, other application methods, or a combination thereof.

The ILD layer 152 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 152 may be formed by chemical vapor deposition (CVD), physical vapor deposition, (PVD), atomic layer deposition (ALD), or other applicable processes.

After the contact etch stop layer 150 and the ILD layer 152 are deposited, a planarization process such as CMP or an etch-back process may be performed until the mask layer 124 is exposed, as shown in FIG. 2M, in accordance with some embodiments.

Afterwards, as shown in FIG. 2N, the mask layer 134 is removed to form a trench (not shown), and a silicide layer 162 and a top S/D contact structure 164 are formed in the trench and over the silicide layer 162, in accordance with some embodiments.

After the trench is formed, the silicide layer 162 may be formed by forming a metal layer over the top surface of the S/D structure 132 and annealing the metal layer so the metal layer reacts with the S/D structure 132 to form the silicide layer 162. The unreacted metal layer may be removed after the silicide layer 162 is formed.

In some embodiments, the top S/D contact structure 164 is made of a conductive material including aluminum (Al), copper (Cu), tungsten (W), titanium (Ti), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. In some embodiments, the top S/D contact structure 164 is formed by chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

Next, as shown in FIG. 2O, an etching stop layer 166 is formed over the top S/D contact structure 164, a dielectric layer 168 is formed over the etching stop layer 166, and a bridge contact structure 170 is formed through the dielectric layer 168 and the etching stop layer 166, in accordance with some embodiments. The bridge contact structure 170 is surrounded by a barrier layer 171.

The bridge contact structure 170 is in direct contact with two adjacent top S/D contact structures 164. Next, an etching stop layer 174 is formed over the bridge contact structure 170, and a dielectric layer 176 is formed over the etching stop layer 174. A front side via structure 178 is formed through the dielectric layer 176 and the etching stop layer 174. The front side via structure 178 is electrically connected to the bridge contact structure 170. The front side via structure 178 is electrically connected to the top S/D structure 132 by the bridge contact structure 170.

In some embodiments, the etching stop layer 166 and the etching stop layer 174 are independently made of a dielectric materials, such as silicon nitride, silicon oxide, silicon oxynitride, another suitable dielectric material, or a combination thereof. In some embodiments, the etching stop layer 166 and the etching stop layer 174 are formed by chemical vapor deposition (CVD), physical vapor deposition, (PVD), atomic layer deposition (ALD), or other applicable processes.

In some embodiments, the dielectric layer 168 and the dielectric layer 176 are independently made of silicon oxide, silicon nitride, silicon oxynitride, phosphosilicate glass (PSG), borophosphosilicate glass (BPSG), and/or other applicable low-k dielectric materials. In some embodiments, the dielectric layer 168 and the dielectric layer 176 are formed by chemical vapor deposition (CVD), physical vapor deposition, (PVD), atomic layer deposition (ALD), or other applicable processes.

In some embodiments, the bridge contact structure 170 and front side via structure 178 are independently made of a conductive material including aluminum (Al), copper (Cu), tungsten (W), titanium (Ti), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof. In some embodiments, the bridge contact structure 170 and front side via structure 178 are formed by chemical vapor deposition (CVD), physical vapor deposition, (PVD), atomic layer deposition (ALD), or other applicable processes.

Afterwards, as shown in FIG. 2P, the substrate 102 is removed from the back side of the substrate 102, in accordance with some embodiments. As a result, a recess 179 is formed to expose the bottom first semiconductor material layer 106b. In addition, the bottom surface of the bottom inner spacer layer 118b is exposed by the recess 179.

Next, as shown in FIG. 2Q, the exposed bottom first semiconductor material layer 106b is removed, in accordance with some embodiments. In some embodiments, the exposed bottom first semiconductor material layer 106b is removed by an etching process, such as dry etching or wet etching process.

Afterwards, as shown in FIG. 2R, a bottom lightly doped drain (LDD) layer 230 is formed in recess 179, and a bottom source/drain (S/D) structure 232 is formed below the bottom LDD layer 230, in accordance with some embodiments. The bottom LDD layer 230 is formed below and in direct contact with the channel layer 108′. The bottom LDD layer 230 has curved sidewall surfaces in direct contact with the curved sidewall surface of the bottom inner spacer layer 118b.

The bottom S/D structure 232 is formed below and in direct contact with the bottom LDD layer 230. The bottom S/D structure 232 is formed below and in direct contact with the bottom inner spacer layer 118b. The width of the bottom S/D structure 232 along the horizontal direction is greater than the width of the bottom LDD layer 230 along the horizontal direction.

The bottom S/D structure 232 is in direct contact with the liner layer 122. The bottom surface of the bottom LDD layer 230 is substantially leveled with the bottom surface of the bottom inner spacer layers 118b. The bottom S/D structure 232 is surrounded by and in direct contact with the liner layer 122.

Next, as shown in FIG. 2S, a silicide layer 262 is formed below the bottom S/D structure 232, and a bottom S/D contact structure 264 is formed below the silicide layer 262 and the bottom S/D structure 232, in accordance with some embodiments. Afterwards, an etching stop layer 266 is formed below the bottom S/D contact structure 264, and a dielectric layer 268 is formed below the bottom S/D contact structure 264. A backside via structure 270 is formed through the dielectric layer 268 and the etching stop layer 266. The backside via structure 270 is electrically connected to the bottom S/D contact structure 264. The backside via structure 270 is electrically connected to the bottom source/drain (S/D) structure 232 by the bottom S/D contact structure 264.

This disclosure provides a vertical GAA device with the channel layer 108′ that extends along the vertical direction. The top S/D structure 132 and the bottom S/D structure 232 are formed on opposite sidewalls of the channel layer 108′. The top S/D contact structure 164 and the bottom S/D contact structure 264 are formed on opposite sidewalls of the channel layer 108′. Since the distance between the gate structure 148 and the top S/D contact structure 164 is increased compared to the GAA device with horizontal channel layer, the capacitor between the gate structure 148 and the top S/D contact structure 164 is reduced. Therefore, the performance of the semiconductor structure 100a is improved.

Furthermore, since the gate structure 148 and the top S/D contact structure 164 are disposed vertically, rather than in parallel to each other, the semiconductor structure 100a does not occupy too much area. The pitch between the gate structure and the S/D contact structure is not limited by the width of the gate structure and the width of the S/D contact structure.

FIG. 2S′ illustrate cross-sectional representations of a semiconductor structure 100b, in accordance with some embodiments. The semiconductor structure 100b of FIG. 2S′ includes elements that are similar to, or the same as, elements of the semiconductor structure 100a of FIG. 2S, the difference between FIG. 2S′ and FIG. 2S is that the topmost surface of the top LDD layer 130 is higher than the top surface of the top inner spacer layer 118a. In addition, the top surface of the top LDD layer 130 is higher than the bottom surface of the top S/D structure 132.

FIG. 2S″ illustrate cross-sectional representations of a semiconductor structure 100c, in accordance with some embodiments. The semiconductor structure 100c of FIG. 2S″ includes elements that are similar to, or the same as, elements of the semiconductor structure 100a of FIG. 2S, the difference between FIG. 2S″ and FIG. 2S is that the topmost surface of the top LDD layer 130 is higher than the top surface of the top inner spacer layer 118a, and the bottommost surface of the bottom LDD layer 230 is lower than the bottom surface of the bottom inner spacer layer 118b. In addition, the bottommost surface of the bottom LDD layer 230 is lower than the top surface of the bottom S/D structure 232.

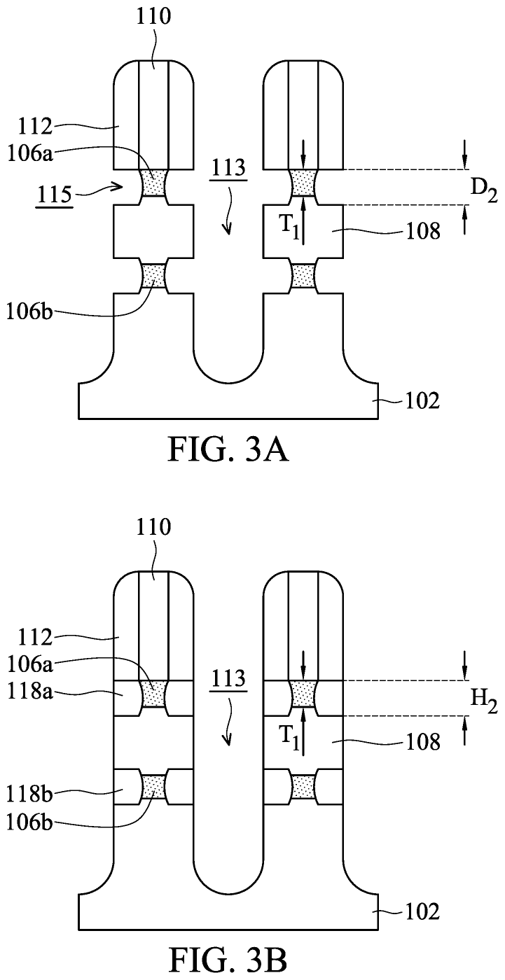

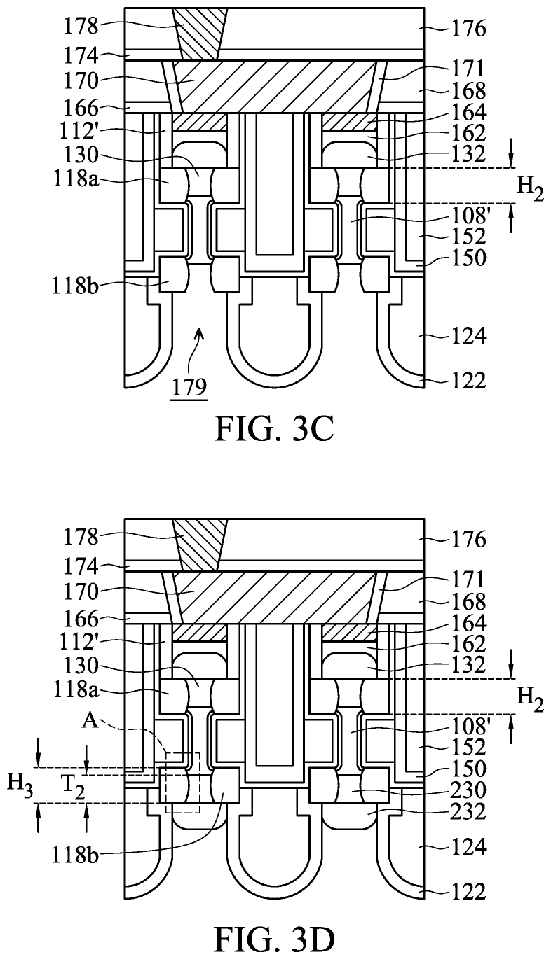

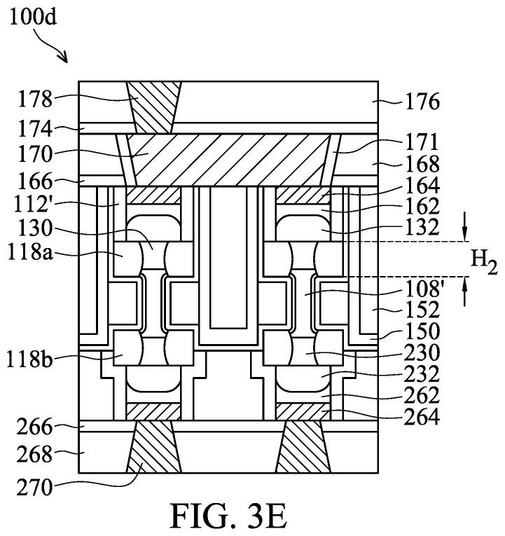

FIGS. 3A to 3E illustrate cross-sectional representations of various stages of manufacturing a semiconductor structure 100d, in accordance with some embodiments. The semiconductor structure 100d of FIGS. 3A-3E includes elements that are similar to, or the same as, elements of the semiconductor structure 100a of FIGS. 2A-2S.

As shown in FIG. 3A, portions of the top first semiconductor material layer 106a and portions of the bottom first semiconductor material layer 106b are removed to form notches 115, in accordance with some embodiments. The notches 115 are exposed by the recess 113. As a result, the etched first semiconductor material layers 106a, 106b have curved outer sidewall surfaces.

The notch 115 has a second depth D₂ along the vertical direction, and the top first semiconductor material layer 106a has the first thickness T₁ along the vertical direction. Therefore, the second depth D₂ of the notch 115 is greater than the first thickness T₁ of the top first semiconductor material layer 106a. In some embodiments, the second depth D₂of the notch 115 in FIG. 3A is greater than the first depth D₁ of the notch 115 in FIG. 2A.

Next, as shown in FIG. 3B, the top inner spacer layer 118a and bottom inner spacer layer 118b are formed in the notches 115, in accordance with some embodiments.

The top inner spacer layer 118a has a second height H₂ along the vertical direction. The second height H₂ of the top inner spacer layer 118a is greater than the first thickness T₁ of the top first semiconductor material layer 106a. In some embodiments, the second height H₂ of the top inner spacer layer 118a in FIG. 3B is greater than the first height H₁ of top inner spacer layer 118a in FIG. 2B.

Afterwards, as shown in FIG. 3C, after the top inner spacer layer 118a and bottom inner spacer layers 118b are formed, several processes illustrated in FIG. 2C to FIG. 2P are performed on the semiconductor structure 100d, in accordance with some embodiments.

As shown in FIG. 3C, the top lightly doped drain (LDD) layer 130 is formed on the channel layer 108′, and the top source/drain (S/D) structure 132 is formed on the top LDD layer 130, in accordance with some embodiments. The channel layer 108′ is surrounded by the gate structure 148, and the gate structure 148 includes the interfacial layer 142, the gate dielectric layer 144, and the gate electrode layer 146.

The silicide layer 162 is formed on the top source/drain (S/D) structure 132, and the top S/D contact structure 164 is formed on the silicide layer 162. The bridge contact structure 170 is formed in the dielectric layer 168 and the etching stop layer 166. The bridge contact structure 170 is in direct contact with two adjacent top S/D contact structures 164. The front side via structure 178 is formed through the dielectric layer 176 and the etching stop layer 174. The front side via structure 178 is electrically connected to the bridge contact structure 170. The bridge contact structure 170 is electrically connected to the top S/D contact structure 164. The front side via structure 178 is electrically connected to the top S/D structure 132 by the bridge contact structure 170 and the top S/D contact structures 164.

The substrate 102 is removed from the back side of the substrate 102 to form the recess 179 and the bottom first semiconductor material layer 106b is exposed. Next, the exposed bottom first semiconductor material layer 106b is removed to expose the bottom surface of the channel layer 108′.

Next, as shown in FIG. 3D, the bottom lightly doped drain (LDD) layer 230 is formed in recess 179, and the bottom source/drain (S/D) structure 232 is formed below the bottom LDD layer 230, in accordance with some embodiments.

The bottom S/D structure 232 is formed on and in direct contact with the bottom LDD layer 230 and the liner layer 122. The bottom surface of the bottom LDD layer 230 is substantially leveled with the bottom surface of the bottom inner spacer layers 118b.

The bottom LDD layer 230 has a second thickness T₂ along the vertical direction. The bottom inner spacer layer 118b has the third height H₃ along the vertical direction. In some embodiments, the second thickness T₂ of the bottom LDD layer 230 is smaller than the third height H₃of the bottom inner spacer layer 118b. The third height H₃ of the bottom inner spacer layer 118b is greater than the second thickness T₂ of the bottom LDD layer 230.

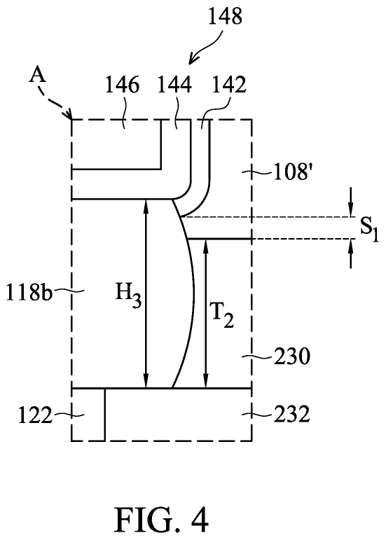

FIG. 4 is an enlarged cross-sectional representation of the semiconductor structure 100d in the region A of FIG. 3D, in accordance with some embodiments.

Since the second height H₂ of the bottom inner spacer layer 118b is greater than the second thickness T₂ of the bottom LDD layer 230, there is a distance S₁ between the interfacial layer 142 of the gate structure 148 and the top surface of the bottom LDD layer 230. In some embodiments, the distance S₁ between the interfacial layer 142 of the gate structure 148 and the top surface of the bottom LDD layer 230 is in a range from about 1 nm to about 5 nm.

The portion of the channel layer 108′ is between the interfacial layer 142 of the gate structure 148 and the top surface of the bottom LDD layer 230. The portion of the channel layer 108′ between the interfacial layer 142 of the gate structure 148 and the top surface of the bottom LDD layer 230 is thick enough to prevent the interfacial layer 142 of the gate structure 148 from being damaged. Therefore, the interfacial layer 142 of the gate structure 148 is not damaged during the etching process for removing the bottom first semiconductor material layer 106b.

Afterwards, as shown in FIG. 3E, the silicide layer 262 is formed below the bottom S/D structure 232, and the bottom S/D contact structure 264 is formed below the silicide layer 262 and the bottom S/D structure 232, in accordance with some embodiments. Afterwards, the backside via structure 270 is formed through the dielectric layer 268 and the etching stop layer 266. The backside via structure 270 is electrically connected to the bottom S/D contact structure 264. The backside via structure 270 is electrically connected to the bottom source/drain (S/D) structure 232 by the bottom S/D contact structure 264. The second height H₂ of the top inner spacer layer 118a in FIG. 3E is greater than the first height H₁ of top inner spacer layer 118a in FIG. 2S.

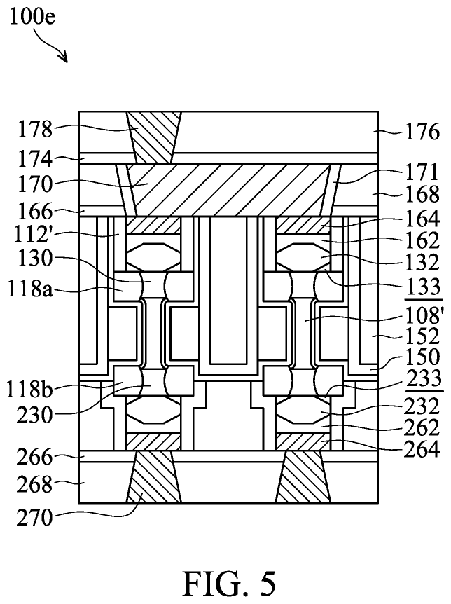

FIG. 5 illustrates a cross-sectional representation of a semiconductor structure 100e, in accordance with some embodiments. The semiconductor structure 100e of FIG. 5 includes elements that are similar to, or the same as, elements of the semiconductor structure 100a of FIGS. 2A-2S.

As shown in FIG. 5, the top lightly doped drain (LDD) layer 130 is formed on the channel layer 108′, and the top source/drain (S/D) structure 132 is formed on the top LDD layer 130. There is a void 133 between the top source/drain (S/D) structure 132 and the thinned spacer layer 112′. In addition, there is another void 233 between the bottom source/drain (S/D) structure 232 and the liner layer 122.

The top S/D structure 132 and the top S/D contact structure 164 are formed over the top surface of the channel layer 108′, and the bottom S/D structure 232 and the bottom S/D contact structure 264 are formed below the bottom surface of the channel layer 108′. Since the distance between the top S/D contact structure 164 and the gate structure 148 is increased due to the position of the vertical channel layer 108′, the unwanted capacitor between the top S/D contact structure 164 and the gate structure 148 is reduced. Therefore, the performance of the semiconductor structure 100e is improved.

It should be noted that same elements in FIGS. 1A to 5 may be designated by the same numerals and may include similar or the same materials and may be formed by similar or the same processes; therefore such redundant details are omitted in the interest of brevity. In addition, although FIGS. 1A to 5 are described in relation to the method, it will be appreciated that the structures disclosed in FIGS. 1A to 5 are not limited to the method but may stand alone as structures independent of the method. Similarly, although the methods shown in FIGS. 1A to 5 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,”“substantially,”“substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes forming a vertical channel layer which is surrounded by the gate structure. The top S/D structure is formed over the channel layer, and the bottom S/D structure is formed below the channel layer. The top S/D contact structure is formed over the top S/D structure, and the bottom S/D contact structure is formed below the bottom S/D structure. Since the distance between the gate structure and the top S/D contact structure in the semiconductor structure with is increased compared to the GAA device with horizontal channel layer, the capacitor between the gate structure and the top S/D contact structure is reduced. Therefore, the performance of the semiconductor structure is improved.

In some embodiments, a semiconductor structure is provided. The semiconductor structure includes a channel layer extending in the vertical direction, and a top S/D structure formed on the channel layer. The semiconductor structure also includes a bottom S/D structure formed below the channel layer, and a gate structure adjacent to the channel layer. The channel layer is surrounded by the gate structure. The semiconductor structure includes a top inner spacer layer formed on the gate structure, and a top surface of the channel layer is higher than a bottom surface of the top inner spacer layer.

In some embodiments, a semiconductor structure is provided. The semiconductor structure includes a channel layer extending along a vertical direction, and a top S/D structure formed on the channel layer. The semiconductor structure includes a bottom S/D structure formed below the channel layer, and the top S/D structure and the bottom S/D structure are formed on opposite sidewall surfaces of the channel layer. The semiconductor structure includes a gate structure adjacent to the channel layer, and the channel layer is surrounded by the gate structure. The semiconductor structure includes a top S/D contact structure formed over the top S/D structure, and a bottom S/D contact structure formed below the bottom S/D structure.

In some embodiments, a method for manufacturing a semiconductor structure is provided. The method includes forming a channel layer over a substrate, and forming a top S/D structure over the channel layer. The method includes forming a gate structure adjacent to the channel layer, and the channel layer is surrounded by the gate structure. The method also includes forming a top S/D contact structure over the top S/D structure, and removing the substrate to form a recess. The method includes forming a bottom S/D structure in the recess, and the bottom S/D structure is below the channel layer. The method also includes forming a bottom S/D contact structure below the bottom S/D structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a channel layer extending along a vertical direction;
a top S/D structure formed on the channel layer;
a bottom S/D structure formed below the channel layer;
a gate structure adjacent to the channel layer, wherein the channel layer is surrounded by the gate structure;
a top inner spacer layer formed on the gate structure, wherein a top surface of the channel layer is higher than a bottom surface of the top inner spacer layer.

2. The semiconductor structure as claimed in claim 1, further comprising:
a top lightly doped drain (LDD) layer formed over the channel layer, wherein a bottom surface of the top LDD layer is higher than the bottom surface of the top inner spacer layer.

3. The semiconductor structure as claimed in claim 1, wherein the top S/D structure is formed on and in direct contact with the top inner spacer layer.

4. The semiconductor structure as claimed in claim 1, further comprising:
a spacer layer formed on the top inner spacer layer, wherein the spacer layer is in direct contact with the top S/D structure.

5. The semiconductor structure as claimed in claim 1, further comprising:
a top S/D contact structure formed over the top S/D structure; and
a bottom S/D contact structure formed below the bottom S/D structure.

6. The semiconductor structure as claimed in claim 1, further comprising:
a bottom inner spacer layer formed below the gate structure, wherein a top surface of the bottom inner spacer layer is higher than a bottom surface of the channel layer.

7. The semiconductor structure as claimed in claim 1, wherein the channel layer has a top portion with a top width, a middle portion with a middle width and a bottom portion with a bottom width, and the middle width of the middle portion is smaller than the top width of the top portion and the bottom width of the bottom portion.

8. The semiconductor structure as claimed in claim 1, further comprising:
a bottom lightly doped drain (LDD) layer formed between the channel layer and the bottom S/D structure.

9. The semiconductor structure as claimed in claim 8, wherein the first gate structure comprises an interfacial layer, and there is a distance between the interfacial layer and the bottom LDD layer.

10. A semiconductor structure, comprising:
a channel layer extending along a vertical direction;
a top S/D structure formed on the channel layer;
a bottom S/D structure formed below the channel layer, wherein the top S/D structure and the bottom S/D structure are formed on opposite sidewall surfaces of the channel layer;
a gate structure adjacent to the channel layer, wherein the channel layer is surrounded by the gate structure; and
a top S/D contact structure formed over the top S/D structure; and
a bottom S/D contact structure formed below the bottom S/D structure.

11. The semiconductor structure as claimed in claim 10, further comprising:
a liner layer formed adjacent to the gate structure and the bottom S/D contact structure, wherein the liner layer is in direct contact with the bottom S/D contact structure.

12. The semiconductor structure as claimed in claim 10, wherein the channel layer has a top portion with a top width, a middle portion with a middle width and a bottom portion with a bottom width, and the middle width of the middle portion is smaller than the top width of the top portion and the bottom width of the bottom portion.

13. The semiconductor structure as claimed in claim 10, further comprising:
a top inner spacer layer formed on the gate structure, wherein the top inner spacer layer is in direct contact with the gate structure.

14. The semiconductor structure as claimed in claim 13, further comprising:
a spacer layer formed on the top inner spacer layer, wherein a width of the spacer layer is smaller than a width of the top inner spacer layer.

15. The semiconductor structure as claimed in claim 10, further comprising:
a bottom inner spacer layer formed below the gate structure, wherein the bottom inner spacer layer is in direct contact with the bottom S/D structure.

16. A method for manufacturing a semiconductor structure, comprising:
forming a channel layer over a substrate;
forming a top S/D structure over the channel layer;
forming a gate structure adjacent to the channel layer, wherein the channel layer is surrounded by the gate structure;
forming a top S/D contact structure over the top S/D structure;
removing the substrate to form a recess;
forming a bottom S/D structure in the recess, wherein the bottom S/D structure is below the channel layer; and
forming a bottom S/D contact structure below the bottom S/D structure.

17. The method for forming the semiconductor structure as claimed in claim 16, further comprising:
forming a top inner spacer layer over the channel layer; and
forming the top S/D structure on and in direct contact with the top inner spacer layer.

18. The method for forming the semiconductor structure as claimed in claim 16, further comprising:
forming a spacer layer before forming the top S/D structure, wherein the top S/D structure is surrounded by the S/D spacer layer; and
thinning the spacer layer to form a thinned spacer layer.

19. The method for forming the semiconductor structure as claimed in claim 16, further comprising:
forming a bottom inner spacer layer below the channel layer, wherein the bottom surface of the bottom inner spacer layer is exposed by the recess.

20. The method for forming the semiconductor structure as claimed in claim 19, further comprising:
forming a liner layer adjacent to the bottom inner spacer layer, wherein the bottom S/D contact structure is surrounded by the liner layer.
